(19) United States
(12) Patent Application Publication
(10) Pub. No.: US 2003/0145461 A1
(43) Pub. Date: Aug. 7, 2003

(54) Semiconductor device and method of manufacturing the same

(76) Inventors: Norihiko Kasai, Sagamihara (JP); Hiromasa Ohno, Yokohama (JP)

Correspondence Address: Mattingly, Stanger & Malur, P.C., Suite 370, 1800 Diagonal Road, Alexandria, VA, 22314, US

(21) Appl. No.: 10/279,986

(22) Filed: Oct. 25, 2002

(30) Foreign Application Priority Data
Feb. 1, 2002 (JP) 2002-025433

(51) Int. Cl. H05K 3/36; H05K 3/02; H05K 3/30

(52) U.S. Cl. 29/832; 29/830; 29/856; 29/846; 29/847

(57) ABSTRACT

A semiconductor device is disclosed which can prevent the leakage of resin and improve the production efficiency. The semiconductor device comprises a substrate, the substrate having plural connecting terminals formed around a recess and plural bump lands arranged side by side around the connecting terminals, a semiconductor chip disposed in the recess, plural wires for connecting pads on the semiconductor chip and the connecting terminals on the substrate with each other, a seal portion embedded in the recess, and plural ball electrodes provided on the bump lands of the substrate. A dummy wiring covered with solder resist is formed in an area between the plural connecting terminals and the plural bump lands on the substrate. According to this construction, a gap between a mold surface of an upper mold and the surface of the substrate, which gap is formed at the time of die clamping, is filled up with the dummy wiring and the solder resist which covers the dummy wiring. Consequently, it is possible to prevent the leakage of sealing resin at the time of injecting the resin and hence possible to improve the production efficiency in molding.

### BACKGROUND OF THE INVENTION

The present invention relates to a semiconductor device manufacturing technique and more particularly to a semiconductor device, the semiconductor device being provided with a recess for mounting a semiconductor chip therein, as well as a technique which is effectively applicable to assembling the semiconductor device.

As examples of a semiconductor device having a semiconductor chip formed with a semiconductor integrated circuit, also having bump electrodes (e.g., solder balls) as external terminals, and further having a wiring substrate for supporting the semiconductor chip, there are known BGA (Ball Grid Array) and CSP (Chip Scale Package).

Recently there has been used a semiconductor device called a cavity type semiconductor package in which a multi-pin type semiconductor chip is used, a heat diffusing plate is attached to a wiring substrate in case of high-temperature heat being generated, and a recess is formed as a cavity structure.

FIGS. 18 and 19 illustrate the structure of a conventional cavity type semiconductor package 20. As to the semiconductor package 20, which is of BGA type, in a sealing step, as shown in FIG. 20, liquid resin 21 dropped by potting with use of a syringe 22 and is dammed by a dam 23 to seal the semiconductor chip 1.

In such application of the liquid resin 21 with use of the syringe 22, however, it is difficult to make control so as to keep the amount of resin constant and it is also difficult to control the resin application time.

Thus, problems are encountered in controllability, causing deterioration of the yield.

Besides, the aforesaid potting work takes much time because the liquid resin 21 is dropped so as not to form voids. Moreover, since the liquid resin applying step is an individual step, a problem remains to be solved also in point of working efficiency and cost.

As a resin sealing method not using the syringe 22 there is known such a transfer molding method as shown in FIG. 17. In transfer molding, there is used a molding die 24 having an upper mold 24a and a lower mold 24b and further having a gate for injecting resin, a wiring substrate 25 with a semiconductor chip 1 mounted thereon is disposed between the upper and lower molds, and thereafter resin is injected through a gate 24c into a cavity 24d of the molding die 24 under the application of heat and pressure to effect resin sealing.

### SUMMARY OF THE INVENTION

The inventor in the present case has found out that the following problems occur in the above transfer molding.

In the semiconductor device of BGA type, as shown in FIG. 17, plural bump electrodes serving as external terminals are formed on the same side as the side where resin molding for the wiring substrate 25 is performed, so on each of bump lands 25c for mounting thereon of the bump electrodes there is formed a solder resist 25a as an insulating film which covers the bump land, with the result that in a bump land area including the plural bump lands 25c there occurs a difference in height, 25b, due to the solder resist 25a.

Therefore, when clamping the wiring substrate 25 by a clamp portion 24e of the upper die 24a, the bump land area is clamped.

If the injecting of resin is performed in this state, the resin which has flowed outside from a cavity 24d further leaks outside through gaps each formed by the difference in height 25b of the solder resist 25a between adjacent bump lands and covers the upper surfaces of the bump lands, thus giving rise to the problem that bump electrodes cannot be mounted onto the bump lands 25c.

If the clamping force in die clamping is enhanced to prevent such leakage of the resin, there arises the problem that internal wiring lines formed in the region corresponding to the die clamping area of the wiring substrate 25 are broken with a high clamping force.

In Japanese Unexamined Patent Publication No. Hei 11(1999)-317472 there is disclosed an associated technique. According to this technique, a projecting portion formed by a laminate of first and second solder resist layers 4, 5 is provided on a wiring substrate just under a molding line, and when an abutment surface of a molding die 14 is abutted against the projecting portion 6 at the time of resin molding, the second solder resist layer 5 as an upper layer of the projecting portion 6 is somewhat crushed by the abutment, allowing a molding resin to be introduced under pressure in a closely contacted state of the second solder resist layer 5 with the abutment surface of the die.

According to such a technique, if a wiring line for the transmission of an electric signal is formed on the surface or in the interior of an area of the wiring substrate corresponding to the abutment surface of the molding die 14, there arises the problem that the wiring line is damaged with the die clamping force, leading to disconnection thereof.

In the foregoing Unexamined Patent Publication No. Hei 11(1999)-317472, there is not found any description taking such disconnection into account.

It is an object of the present invention to provide a semiconductor device and a method of manufacturing the same, which can prevent the leakage of resin and improve the production efficiency.

It is another object of the present invention to provide a semiconductor device and a method of manufacturing the same, which can improve the space efficiency.

The above and other objects and novel features of the present invention will become apparent from the following description and the accompanying drawings.

Typical inventions as disclosed herein will be outlined below.

In a first aspect of the present invention there is provided a semiconductor device comprising:

a substrate having a main surface formed with a recess which is enclosed with an inner periphery wall, the substrate further having a plurality of connecting terminals formed around the recess and a plurality of external terminal connecting electrodes which are formed on the main surface so as to be arranged side by side around the connecting terminals;

a semiconductor chip disposed in the recess;

a plurality of electrically conductive members for connecting surface electrodes on the semiconductor chip and the connecting terminals electrically with each other;

a seal portion embedded in the recess to seal the semiconductor chip and the plural conductive members with resin; and

a plurality of external terminals formed on the external terminal connecting electrodes and connected electrically with the semiconductor chip,

wherein a dummy wiring covered with an insulating film is formed in an area of the main surface located between the plural connecting terminal and the plural external terminal connecting electrodes on the substrate.

In a second aspect of the present invention there is provided, in combination with the above first aspect, a semiconductor device wherein the dummy wiring is formed in the shape of a frame correspondingly to the arrangement of the connecting terminals.

In a third aspect of the present invention there is provided, in combination with the above first aspect, a semiconductor device wherein the dummy wiring is formed in the shape of a frame which corresponds to the arrangement of the connecting terminals and which is interrupted at corners.

In a fourth aspect of the present invention there is provided, in combination with the above first aspect, a semiconductor device wherein internal wiring lines are formed at positions corresponding to the dummy wiring.

In a fifth aspect of the present invention there is provided, in combination with the above first aspect, a semiconductor device wherein the substrate comprises a wiring substrate and a heat diffusing plate, and the electrically conductive members are fine metallic wires which are connected to the connecting terminals while spanning the inner periphery wall of the recess.

In a sixth aspect of the present invention there is provided a semiconductor device comprising:

a substrate having a main surface formed with a recess which is enclosed with an inner periphery wall, the substrate further having a plurality of connecting terminals formed around the recess and a plurality of external terminal connecting electrodes formed on the main surface so as to be arranged side by side around the connecting terminals;

a semiconductor chip disposed in the recess;

a plurality of electrically conductive members for connecting surface electrodes on the semiconductor chip and the connecting terminals electrically with each other;

a seal portion embedded in the recess to seal the semiconductor chip and the plural conductive members with resin; and

a plurality of external terminals formed on the external terminal connecting electrodes and connected electrically with the semiconductor chip,

wherein a plurality of dummy through-hole wiring lines are formed in an area of the main surface located between the plural connecting terminals and the plural external terminal connecting electrodes on the substrate.

In a seventh aspect of the present invention there is provided, in combination with the above sixth aspect, a semiconductor device wherein surface wiring lines for connecting the connecting terminals and the external terminal connecting electrodes with each other are formed between adjacent said dummy through-hole wiring lines on the main surface.

In an eighth aspect of the present invention there is provided, in combination with the above sixth aspect, a semiconductor device wherein the substrate comprises a wiring substrate and a heat diffusing plate, the electrically conductive members are fine metallic wires which are connected to the connecting terminals while spanning the inner periphery wall of the recess.

In a ninth aspect of the present invention there is provided a method of manufacturing a semiconductor device, comprising the steps of:

providing a substrate, the substrate having a main surface formed with a recess which is enclosed with an inner periphery wall, the substrate further having a plurality of connecting terminals formed around the recess and a plurality of external terminal connecting electrodes which are formed on the main surface so as to be arranged side by side around the connecting terminals, with a dummy wiring being formed between the plural connecting terminals and the plural external terminal connecting electrodes, the dummy wiring being covered with an insulating film;

mounting a semiconductor chip in the recess of the substrate;

connecting surface electrodes on the semiconductor chip and the connecting terminals formed around the recess of the substrate with each other through a plurality of metal wires while allowing the metal wires to span the inner periphery wall of the recess;

disposing the substrate onto a first mold of a molding die which comprises the first mold and a second mold in a pair, and thereafter clamping the substrate by the first and second molds so that the second mold presses from above the dummy wiring and the external terminal connecting electrodes on the substrate while allowing the semiconductor chip and the plural metal wires to be covered with a cavity of the second mold;

injecting a sealing resin into the cavity under pressure to form a seal portion; and

forming a plurality of external terminals on the substrate, the external terminals being electrically connected to the semiconductor chip.

In a tenth aspect of the present invention there is provided, in combination with the above ninth aspect, a method of manufacturing a semiconductor device wherein the dummy wiring on the substrate is formed in the shape of a frame outside the plural connecting terminals, the frame being interrupted at corners thereof, and during the pressure-injecting of the sealing resin into cavity, the resin is filled into the cavity while allowing air present within the cavity to escape to the exterior from the interrupted corner portions of the dummy wiring.

In an eleventh aspect of the present invention there is provided a method of manufacturing a semiconductor device, comprising the steps of:

providing a substrate, the substrate having a main surface formed with a recess which is enclosed with an inner periphery wall, the substrate further having a plurality of connecting terminals formed around the recess and a plurality of external terminal connecting electrodes which are formed on the main surface so as to be arranged side by side around the connecting terminals, with a plurality of dummy through-hole wiring lines being formed between the plural connecting terminals and the plural external terminal connecting electrodes, the dummy through-hole wiring lines being covered with an insulating film;

mounting a semiconductor chip in the recess of the substrate;

connecting surface electrodes on the semiconductor chip and the connecting terminals formed around the recess of the substrate with each other through a plurality of metal wires while allowing the metal wires to span the inner periphery wall of the recess;

disposing the substrate onto a first mold of a molding die which comprises the first mold and a second mold in a pair, and thereafter clamping the substrate by the first and second molds so that the second mold presses from above the dummy through-hole wiring lines and the external terminal connecting electrodes on the substrate while allowing the semiconductor chip and the plural metal wires to be covered with a cavity of the second mold;

injecting a sealing resin into the cavity under pressure to form a seal portion; and

forming a plurality of external terminals on the substrate, the external terminals being electrically connected to the semiconductor chip.

In a twelfth aspect of the present invention there is provided, in combination with the above eleventh aspect, a method of manufacturing a semiconductor device wherein surface wiring lines for connecting the connecting terminals and the external terminal connecting electrodes with each other are formed between adjacent said dummy through-hole wiring lines on the main surface, and the dummy through-hole wiring lines and the surface wiring lines are pressed from above by the second mold.

In a thirteenth aspect of the present invention there is provided, in combination with the above eleventh aspect, a method of manufacturing a semiconductor device wherein the sealing resin is filled into the cavity while allowing air present within the cavity to escape to the exterior from corner portions of the cavity.

In a fourteenth aspect of the present invention there is provided a method of manufacturing a semiconductor device, comprising the steps of:

providing a substrate, the substrate having a main surface formed with a recess which is enclosed with an inner periphery wall, the substrate further having a plurality of connecting terminals formed around the recess and a plurality of external terminal connecting electrodes which are formed on the main surface so as to be arranged side by side around the connecting terminals;

providing a molding die which comprises first and second molds in a pair, the second mold having a mold surface corresponding to the plural external terminal connecting electrodes and also having a projecting mold surface projecting from the mold surface;

mounting a semiconductor chip in the recess of the substrate;

connecting surface electrodes on the semiconductor chip and the connecting terminals formed around the recess of the substrate with each other through a plurality of metal wires while allowing the metal wires to span the inner periphery wall of the recess;

disposing the substrate onto the first mold, thereafter pressing the external terminal connecting electrodes by the mold surface of the second mold while allowing the semiconductor chip and the plural metal wires to be covered with a cavity of the second mold, and clamping the substrate by the first and second molds so that an area of the main surface located between the external terminal connecting electrodes and the connecting terminals is pressed by the projecting mold surface of the second mold;

injecting a sealing resin into the cavity under pressure to form a seal portion; and

forming a plurality of external terminals on the substrate, the external terminals being electrically connected to the semiconductor chip.

In a fifteenth aspect of the present invention there is provided, in combination with the above fourteenth aspect, a method of manufacturing a semiconductor device wherein the substrate has internal wiring lines formed in the area between the external terminal connecting electrodes and the connecting terminals, and the main surface on the internal wiring lines is pressed by the projecting mold surface of the second mold.

In a sixteenth aspect of the present invention there is provided, in combination with the fourteenth aspect, a method of manufacturing a semiconductor device wherein the sealing resin is filled into the cavity while allowing air present within the cavity to escape to the exterior from corner portions of the cavity.

### BRIEF DESCRIPTION OF THE DRAWINGS

FIG. 1 is a plan view showing an example of an external terminal-side structure of a semiconductor device (BGA) according to a first embodiment of the present invention;

FIG. 2 is a sectional view showing the structure of the BGA shown in FIG. 1;

FIG. 3 is a plan view showing the structure of a substrate used in manufacturing the BGA shown in FIG. 1;

FIG. 4 is a plan view showing the structure of a substrate according to a modification of the first embodiment;

FIG. 5 is an enlarged partial sectional view showing an example of a die clamping state in a molding step in the manufacture of BGA using the substrate shown in FIG. 3;

FIG. 6 is a plan view showing the structure of a substrate used in manufacturing a BGA according to a second embodiment of the present invention;

FIG. 7 is an enlarged partial plan view showing the structure of portion A in FIG. 6;

FIG. 8 is an enlarged partial sectional view showing an example of a die clamping state in a molding step in the manufacture of BGA using the substrate shown in FIG. 6;

FIG. 9 is a plan view showing the structure of a cavity and clamp portion of an upper mold in a molding die which is used in manufacturing a BGA according to a third embodiment of the present invention;

FIG. 10 is an enlarged partial sectional view showing an example of a die clamping state using the upper mold shown in FIG. 9;

FIGS. 11(a) and 11(b) illustrate the structure of a cavity and clamp portion of an upper mold in a molding die which is used in manufacturing a BGA according to a fourth embodiment of the present invention, of which FIG. 11(a) is a plan view and FIG. 11(b) is an enlarged partial plan view showing a detailed structure of portion A in FIG. 11(a);

FIGS. 12(a) and 12(b) illustrate an example of a die clamping state using the upper mold shown in FIG. 11, of which FIG. 12(a) is an enlarged partial sectional view and FIG. 12(b) is an enlarged partial sectional view taken along line C-C in FIG. 11(b);

FIG. 13 is a plan view showing an example of a structure after wire bonding in the manufacture of the BGA according to the fourth embodiment;

FIG. 14 is a sectional view showing a sectional structure taken along line B-B of the substrate shown in FIG. 13;

FIG. 15 is an enlarged partial sectional view of the substrate shown in FIG. 14;

FIG. 16 is a plan view showing an example of a structure after resin molding in the manufacture of the BGA according to the fourth embodiment of the present invention;

FIG. 17 is an enlarged partial sectional view showing a die clamping state in transfer molding as a comparative example in association with the present invention;

FIG. 18 is a plan view showing an external terminal-side structure of a conventional BGA having been subjected to sealing by potting;

FIG. 19 is a sectional view showing the structure of the conventional BGA shown in FIG. 18; and

FIG. 20 is a sectional view showing the state of potting in a sealing step in the manufacture of the conventional BGA shown in FIG. 18.

### DETAILED DESCRIPTION OF PREFERRED EMBODIMENTS

Embodiments of the present invention will be described in detail hereinunder with reference to the accompanying drawings. In all of the drawings illustrating the embodiments, portions having the same functions are identified by like reference numerals, and repeated explanations will be omitted.

(First Embodiment)

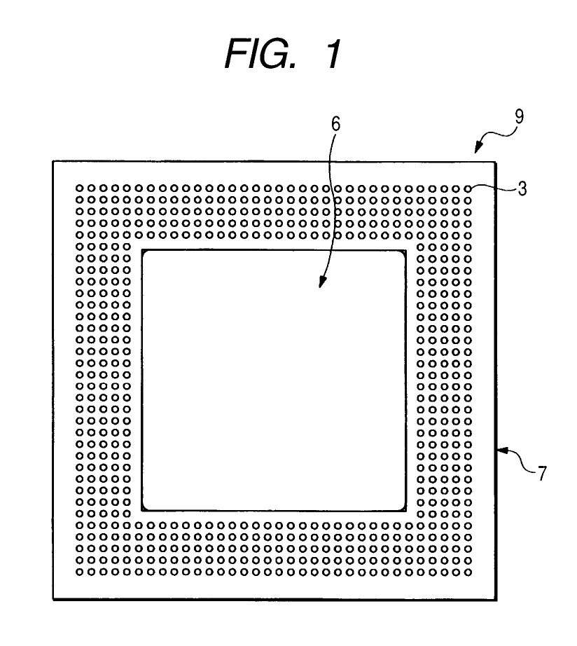

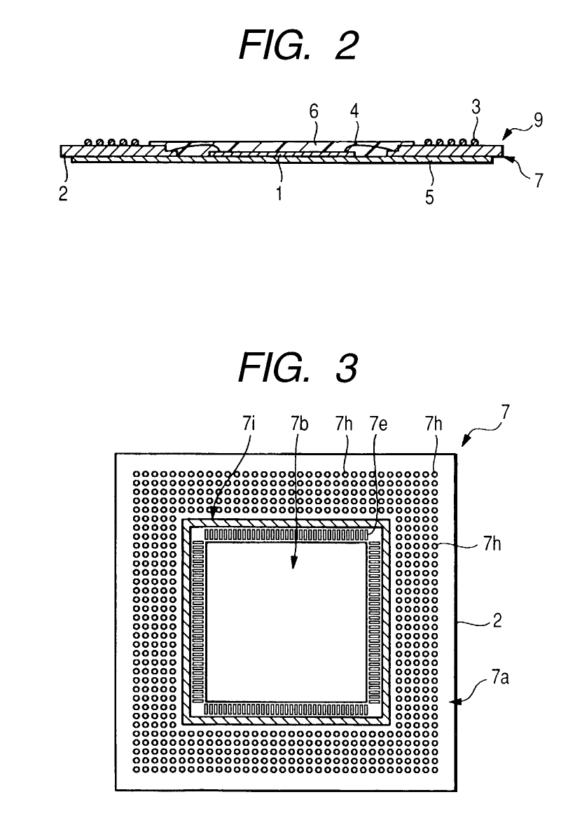

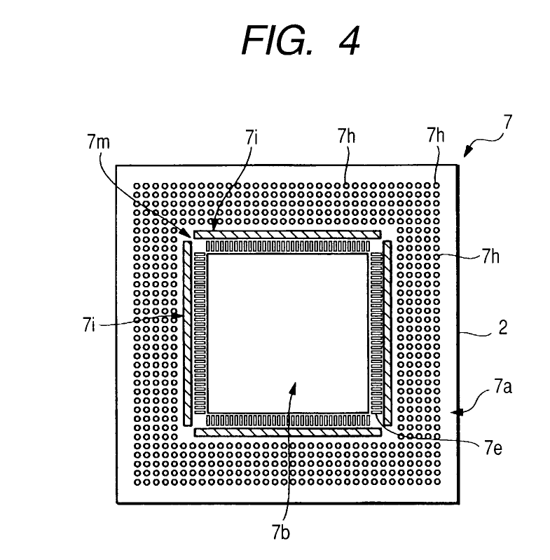

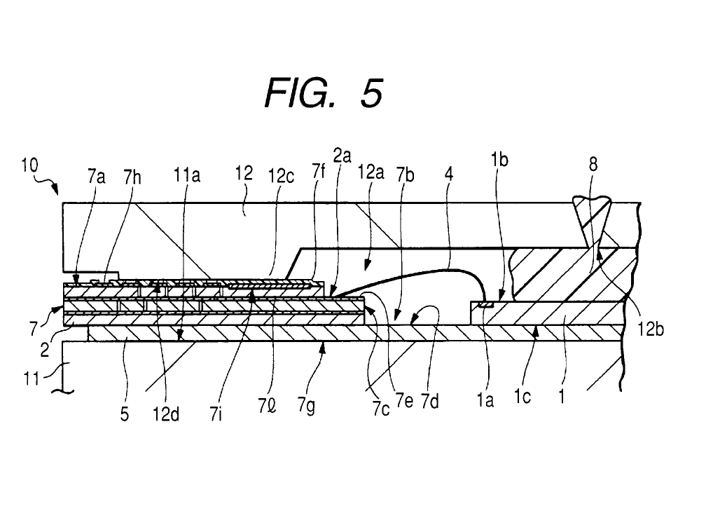

FIG. 1 is a plan view showing an example of an external terminal-side structure of a semiconductor device (BGA) according to a first embodiment of the present invention, FIG. 2 is a sectional view showing the structure of the BGA illustrated in FIG. 1, FIG. 3 is a plan view showing the structure of a substrate used in manufacturing the BGA shown in FIG. 1, FIG. 4 is a plan view showing the structure of a substrate according to a modification of the first embodiment, and FIG. 5 is an enlarged partial sectional view showing an example of a die clamping state in a molding step in the manufacture of BGA using the substrate illustrated in FIG. 3.

The semiconductor device of this first embodiment is of a cavity structure in which a semiconductor chip 1 having a semiconductor integrated circuit is mounted in a recess (also called a cavity) 7b of a substrate 7. It is also a wire bonding type and further it is a semiconductor package of a molded type in which the sealing of the semiconductor chip 1 with resin is performed by transfer molding.

Further, as shown in FIG. 1, the semiconductor device of this first embodiment is a BGA 9 in which external terminals are ball electrodes 3 formed with solder for example and such plural ball electrodes 3 are arranged in plural rows around a seal portion 6.

For improving the heat radiating performance of the semiconductor chip 1, which is a multi-pin chip, the substrate 7 comprises a wiring substrate 2 and a heat diffusing plate 5, which are bonded together with an adhesive for example.

More specifically, as shown in FIG. 5, the substrate 7 is formed by bonding a wiring substrate 2 having plural wiring lines with a heat diffusing plate 5 formed of a material high in thermal conductivity. The recess 7b formed in the substrate 7 comprises an inner periphery wall 7c and a bottom 7d. The inner periphery wall 7c is formed in the wiring substrate 2, while the bottom 7d is formed in the heat diffusing plate 5. A back side 1c of the semiconductor chip 1 is fixed onto the bottom 7d through an adhesive so that the heat radiating performance of the chip can be improved.

A description will now be given about a detailed construction of the BGA 9. As shown in FIG. 5, the BGA 9 comprises the substrate 7, the semiconductor chip 1, plural wires (electrically conductive members) 4 as metal wires, a seal portion 6 shown in FIG. 1, and plural ball electrodes 3. The substrate 7 has a land forming surface (main surface) 7a and a back side 7g as an opposite side, in which land forming surface 7a is formed the recess 7b enclosed with the inner periphery wall 7c. The substrate 7 is further provided with plural connecting terminals 7e formed around the recess 7b and plural bump lands (external terminal connecting electrodes) 7h arranged around the connecting terminals 7e on the land forming surface 7a. The semiconductor chip 1 is disposed on the heat diffusing plate 5 which is the bottom 7d of the recess 7b. The wires 4 connects pads (surface electrodes) 1a formed on a main surface 1b of the semiconductor chip 1 electrically with connecting terminals 7e which are formed around the recess 7b of the substrate 7 correspondingly to the pads 1a. The seal portion 6 is embedded in the recess 7b to seal the semiconductor chip 1 and the plural wires 4 with resin. The ball electrodes 3 are electrically connected with the semiconductor chip 1 and are disposed on the bump lands 7h of the land forming surface 7a of the substrate 7.

Further, as shown in FIGS. 3 and 5, a dummy wiring 7i covered with a solder resist 7f as an insulating film is formed in an area between the plural connecting terminals 7e and the plural bump lands 7h on the substrate 7. The transmission of an electric signal is not performed in the dummy wiring 7i.

The wiring substrate 2 provided with the land forming surface 7a and the heat diffusing plate 5 provided with the back side 7g are bonded together to constitute the substrate 7. The recess 7b is formed in the land forming surface 7a and the pads of the semiconductor chip 1 mounted in the recess 7b are connected to the connecting terminals 7e through plural wires 4 which span the inner periphery wall 7c of the recess 7b.

In a resin molding step as an assembling step for the BGA 9, there is performed sealing with resin by transfer molding to assemble the BGA.

Therefore, in the resin molding step as shown in FIG. 5, the dummy wiring 7i is disposed so that when the substrate 7 is clamped with a clamp portion 12c of an upper mold 12 as a second mold of a molding die 10, the clamp portion 12c presses the dummy wiring 7i from above.

With this arrangement, when sealing resin 8 is filled into a cavity 12a of the upper mold 12, the sealing resin 8 which tends to flow out from the cavity 12a can be blocked by the dummy wiring 7i.

That is, the dummy wiring 7i eliminates the gap between a die surface 12d of the clamp portion 12c of the upper mold 12 and the surface of the substrate 7 at the time of die clamping, whereby the leakage of resin can be prevented.

As shown in FIG. 3, therefore, the dummy wiring 7i is formed in the shape of a frame correspondingly to the arrangement of the connecting terminals 7e so as to isolate the area of the group of connecting terminals 7e and that of the group of bump lands 7h from each other.

This is effective for BGA 9 using a multi-layer printed circuit board.

However, since the dummy wiring 7i is formed in the area between the group of connecting terminals 7e and the group of bump lands 7h, it is impossible to form any other wiring in the area.

In view of this point, as shown in FIG. 5, a stepped portion 2a is formed as a depression in an opening edge of the recess 7b and connecting terminals 7e connected to the wires 4 are arranged side by side in the stepped portion 2a and are electrically connected through internal wiring lines 71 to the bump lands 7h formed on the substrate surface.

Thus, even in case of using such a substrate 7 as internal wiring lines 71 are formed below the dummy wiring 7i, the leakage of resin can be prevented by the dummy wiring 7i even without the application of any high pressure at the time of clamping of the molding die 10.

As in a substrate according to a modification shown in FIG. 4, the dummy wiring 7i may be formed in the shape of a frame which is interrupted at corners thereof.

By thus forming the dummy wiring 7i in the shape of a corner-interrupted frame, the portions where the dummy wiring 7i is interrupted serve as air vent substitute portions 7m, with consequent decrease in the surface height of the solder resist 7f. Therefore, even without forming air vents in the upper mold 12 of the molding die 10, gaps are formed in the corners where the dummy wiring 7i is interrupted and the gaps can be used as a substitute for air vents, permitting air to be drawn out from the gaps at the time of filling of the resin.

Consequently, the upper mold 12 can be made simple in structure.

The sealing resin 8 for forming the seal portion 6 is a resin for transfer molding, e.g., a thermosetting epoxy resin.

The wires (electrically conductive members) 4 as metal wires are gold wires for example.

The following description is now provided about a method of manufacturing the BGA 9 of this first embodiment.

First, the substrate 7 shown in FIG. 3 is provided. The substrate 7 has a land forming surface 7a formed with a recess 7b enclosed by an inner periphery wall 7c. The substrate 7 is further provided with plural connecting terminals 7e formed on a stepped portion 2a which is formed around an edge of the recess 7b, plural bump lands 7h formed around the outside of the connecting terminals 7e so as to be arranged side by side on the land forming surface 7a, and a dummy wiring 7i formed in the shape of a frame between the connecting terminals 7e and the bump lands 7h, the dummy wiring 7i being covered with solder resist 7f.

Subsequently, there is performed die bonding in which a semiconductor chip 1 is mounted onto a bottom 7d of the recess 7b in the substrate 7, as shown in FIG. 5.

More specifically, the semiconductor chip is mounted through an adhesive onto the bottom 7b of the recess 7b which bottom is constituted by a heat diffusing plate 5.

Thereafter, pads 1a of the semiconductor chip 1 and the connecting terminals 7e arranged around the recess 7b of the substrate 7 correspondingly to the pads 1a are electrically connected together through wires (electrically conductive members) 4 as metal wires.

In this case, the connecting terminals 7e are provided on the stepped portion 2a formed around the edge of the recess 7b, so at the time of wire bonding, the wires 4 are allowed to span the inner periphery wall 7c of the recess 7b and in this state the pads 1a of the semiconductor chip 1 and the connecting terminals 7e are connected together.

After the wire bonding, resin sealing is performed by transfer molding with use of a molding die 10 which comprises a lower mold (first mold) 11 and an upper mold (second mold) 12, both making a pair.

First, the substrate 7 after wire bonding is disposed on a mold surface 11a of the lower mold 11, then with the semiconductor chip 1 and the plural wires 4 covered with a cavity 12a of the upper mold 12, the substrate 7 is clamped by the upper mold 12 and lower mold 11 in such a manner that a mold surface 12d of a clamp portion 12c of the upper mold 12 presses from above the dummy wiring 7i and the bump lands 7h of the substrate.

At this time, since the dummy wiring 7i formed on the land forming surface 7a is pressed by the mold surface 12d of the clamp portion 12c of the upper mold 12, the gap formed between the mold surface 12d and the surface of the substrate 7 at the time of die clamping is filled up by both dummy wiring 7i and solder resist 7f which covers the dummy wiring, thus giving rise to a gap-free state.

In this die clamped state, if sealing resin 8 is injected under pressure into the cavity 12a from a gate 12b of the upper mold 12, it is possible to prevent leakage of the sealing resin 8.

Thus, the transfer molding can be controlled stably and it is possible to improve the production efficiency in molding.

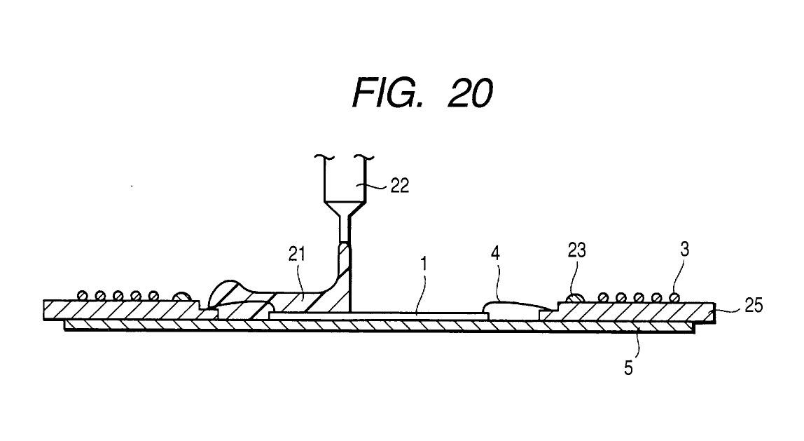

Moreover, since it is possible to control the transfer molding stably, it is possible to improve the space efficiency in comparison with the conventional potting method shown in FIG. 20. That is, it becomes possible to easily effect a transfer molding improved in space efficiency.

Besides, since the dummy wiring 7i is formed in the area of the substrate 7 which area is pressed by the upper mold 12, if a comparison is made on the assumption that the die clamping force is equal to that in the absence of the dummy wiring 7i, it is possible to diminish the stress imposed on wiring per unit area because the total wiring area on the land forming surface 7a of the substrate 7 increased by the dummy wiring 7i.

As a result, if the substrate 7 has internal wiring lines 71 for example below the dummy wiring 7i, it is possible to prevent breaking of the internal wiring lines 71.

Further, as in the modification shown in FIG. 4, if the dummy wiring 7i is formed in such a frame shape as is interrupted at corners thereof, gaps are formed in the interrupted corners of the dummy wiring 7i at the time of mold clamping, so it is possible to use the gaps as air vent substitutes 7m.

That is, when filling the resin, it is possible to draw out air from the air vent substitutes 7m as the aforesaid gaps, thus permitting the omitting of air vents in the upper mold 12. Consequently, it is possible to simplify the structure of the upper mold 12.

After completion of the filling of the sealing resin 8 into the cavity 12a and hardening thereof, the upper mold 12 and lower mold 11 are opened and the substrate 7 after the molding is taken out.

Thereafter, plural ball electrodes (external terminals) 3 are provided on the substrate 7 in electric connection with the semiconductor chip 1.

To be more specific, ball electrodes 3, which are constituted by solder for example, are provided respectively on the bump lands 7h formed on the land forming surface 7a of the substrate 7 to complete the assembly of BGA 9.

Although the dummy wiring 7i in the first embodiment does not perform the transmission of an electric signal, the dummy wiring 7i may be electrically connected to the semiconductor chip 1. For example, the dummy wiring 7i may utilized as wiring for the feed of a ground potential to the semiconductor chip 1.

(Second Embodiment)

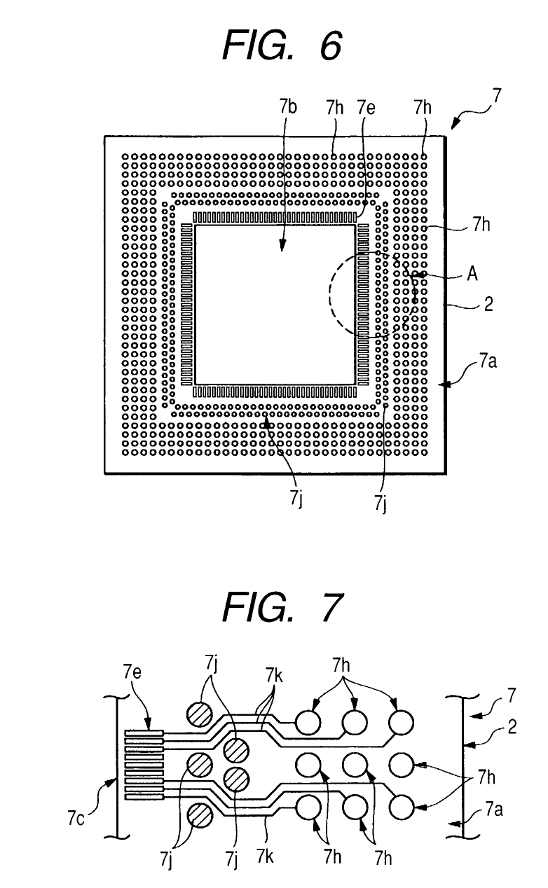

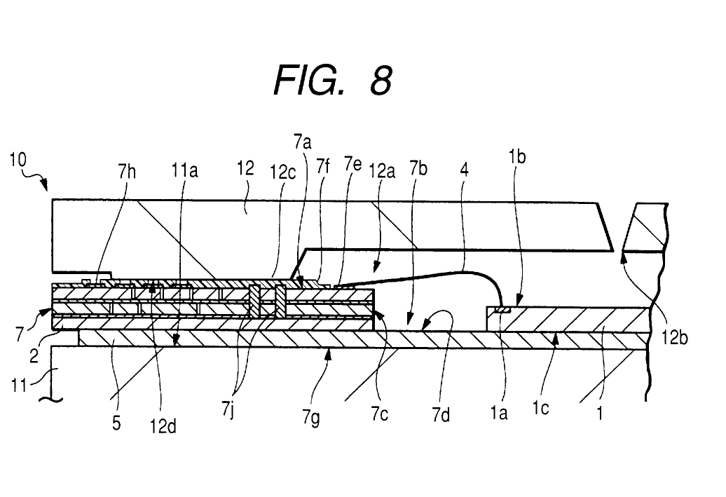

FIG. 6 is a plan view showing the structure of a substrate which is used in manufacturing a BGA according to a second embodiment of the present invention, FIG. 7 is an enlarged partial plan view showing the structure of portion A in FIG. 6, and FIG. 8 is an enlarged partial sectional view showing an example of a die clamping state in a molding step in the manufacture of BGA using the substrate illustrated in FIG. 6.

Similarly to the first embodiment, the semiconductor device of this second embodiment shown in FIG. 6 has a cavity structure and is a wire bonding type and BGA type semiconductor device which is assembled through resin molding by transfer molding. The semiconductor device of this second embodiment is different from the BGA 9 of the first embodiment in that, as shown in FIG. 8, not dummy wiring 7i but plural dummy through-hole wiring lines 7j are formed in the thickness direction of a substrate 7 in an area of a land forming surface 7a located between plural connecting terminals 7e and plural bump lands 7h on the substrate 7.

The dummy through-hole wiring lines 7j are covered on their surface-side end faces with solder resist 7f and do not perform the transmission of an electric signal.

Since the dummy through-hole wiring lines 7j are formed in the thickness direction of the substrate 7, they serve as supports to enhance the strength of the substrate.

Consequently, it is possible to prevent breaking of such internal wiring lines 71 as shown in FIG. 5 which are formed below and correspondingly to a clamp portion 12c of an upper mold 12.

Further, in the case of the substrate 7 provided with the dummy through-hole wiring lines 7j, as shown in FIG. 7, surface wiring lines 7k which connect the connecting terminals 7e and the bump lands 7h with each other can be formed between adjacent dummy through-hole wiring lines 7j on the land forming surface 7a.

With the dummy through-hole wiring lines 7j provided, even if the upper mold 12 is clamped with a clamping force strong enough to crush concaves and convexes of the solder resist located above the wiring lines 7j, the dummy through-hole wiring lines 7j act as posts and support the upper mold, so that it is possible to form wiring lines also on the substrate surface.

Thus, since the surface wiring lines 7k can be formed between adjacent dummy through-hole wiring lines 7j, it is possible to enhance the freedom of wiring, particularly the freedom of wiring for the land forming surface 7a, i.e., the surface wiring lines 7k. As shown in FIG. 8, plural connecting terminals 7e can also be formed on the same land forming surface 7a as the bump lands 7h.

As a result, the connecting terminals 7e and the bump lands 7h can be connected together through the surface wiring lines 7k, as shown in FIG. 7.

At the time of die clamping, therefore, by clamping the die with such a high clamping force as causes collapse of concaves and convexes of the solder resist 7f and by injecting resin in this state, it is possible to prevent the leakage of resin while preventing disconnection of the internal wiring lines 71 and the surface wiring lines 7k.

Consequently, it is possible to control transfer molding stably and improve the production efficiency in molding.

As to other structural points, how to manufacture, and other effects of the BGA of this second embodiment, they are the same as those described in the first embodiment, so tautological explanations thereof will here be omitted.

(Third Embodiment)

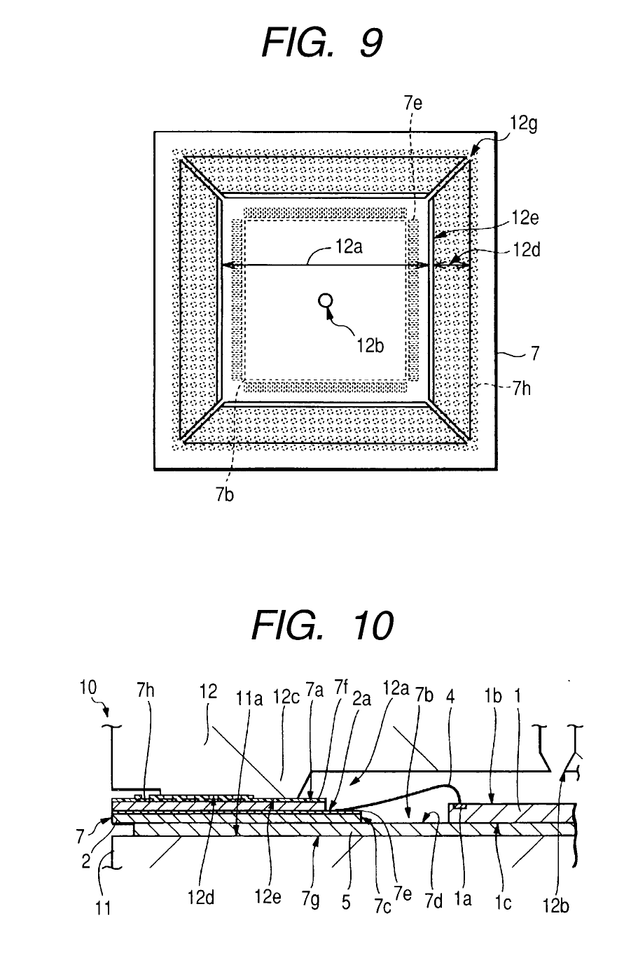

FIG. 9 is a plan view showing the structure of a cavity and a clamp portion of an upper mold in a molding die used in the manufacture of a BGA according to a third embodiment of the present invention, and FIG. 10 is an enlarged partial sectional view showing an example of a die clamping state using the upper mold shown in FIG. 9.

In this third embodiment, a mold surface 12d of a clamp portion 12c of an upper mold (second mold) 12 in a molding die 10 is stepped as in FIG. 10. In a resin molding step in assembling the BGA type semiconductor device, transfer molding is carried out using the upper mold 12, the upper mold 12 having a mold surface 12d which corresponds to plural bump lands 7h and also having a projecting mold surface 12e formed inside the mold surface 12d and projecting from the same mold surface.

FIG. 9 illustrates the cavity 12a, mold surface 12d and projecting mold surface 12e of the upper mold 12 and also illustrates a positional relation thereof to a substrate 7 in a transmittancewise manner.

Air vents 12g are formed in four corners of the cavity 12a and the injecting of resin is performed while allowing air to escape to the exterior through the air vents 12g from the corners of the cavity.

As shown in FIG. 10, the projecting mold surface 12e of the clamp portion 12c of the upper mold 12 is projected in an area inside the mold surface 12d so that at the time of die clamping an area inside the bump lands 7h on the land forming surface 7a of the substrate is sure to be pressed by the projecting mold surface 12e.

The amount of projection of the projecting mold surface 12e from the mold surface 12d should be made larger than at least half of the film thickness of the surface wiring lines 7k. This is preferable for preventing the leakage of resin in a more positive manner. For example, the aforesaid amount of projection is 0.02 mm or so, whereby at the time of die clamping the area inside the bump lands 7h formed on the land forming surface 7a of the substrate 7 can be pressed positively by the projecting mold surface 12e.

In resin molding, therefore, the surface of the solder resist 7f on the bump lands 7h is pressed by the mold surface 12d of the upper mold 12 and the solder resist 7f present inside the bump lands 7h is clamped positively by the projecting mold surface 12e, thus making it possible to effect resin molding.

Consequently it is possible to prevent the leakage of resin at the time of injecting resin, control the transfer molding stably, and improve the production efficiency in molding.

Even in the case where such internal wiring lines 71 as shown in FIG. 5 are formed in the substrate 7, if resin molding is carried out using the molding die 10 according to this third embodiment, the solder resist 7f on the land forming surface 7a which overlie the internal wiring lines 7l can be pressed without the need of enhancing the clamping force in mold clamping, because the upper mold 12 is provided with the projecting mold surface 12e. As a result, it becomes possible to prevent the leakage of resin without causing disconnection of the internal wiring lines 7l.

Other structural points, how to manufacture, and other effects of the semiconductor device of this third embodiment are the same as in the first embodiment, so tautological explanations thereof will here be omitted.

(Fourth Embodiment)

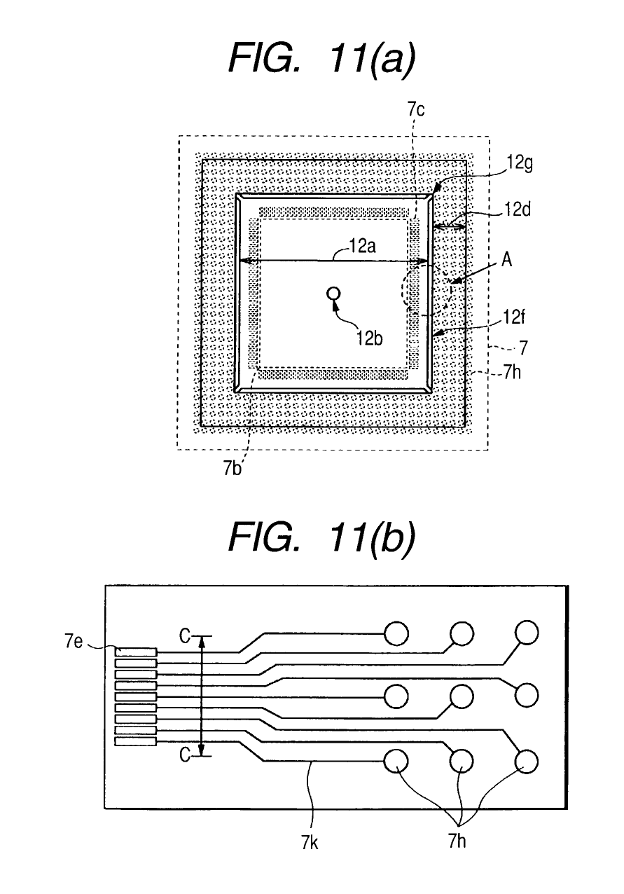

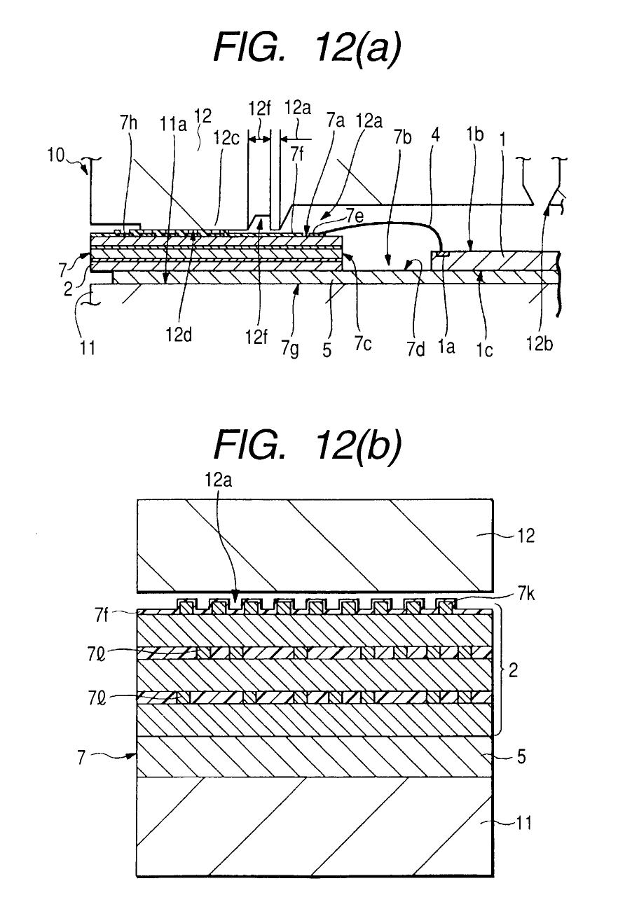

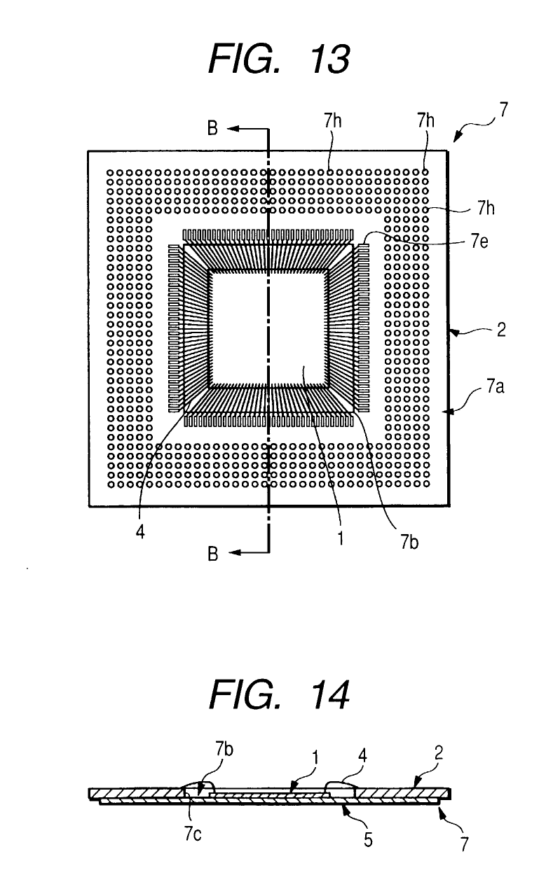

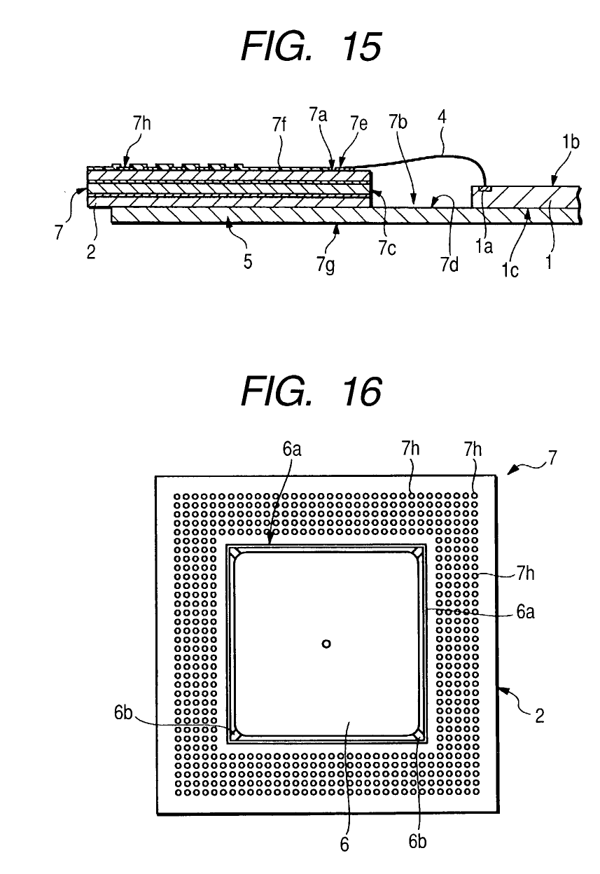

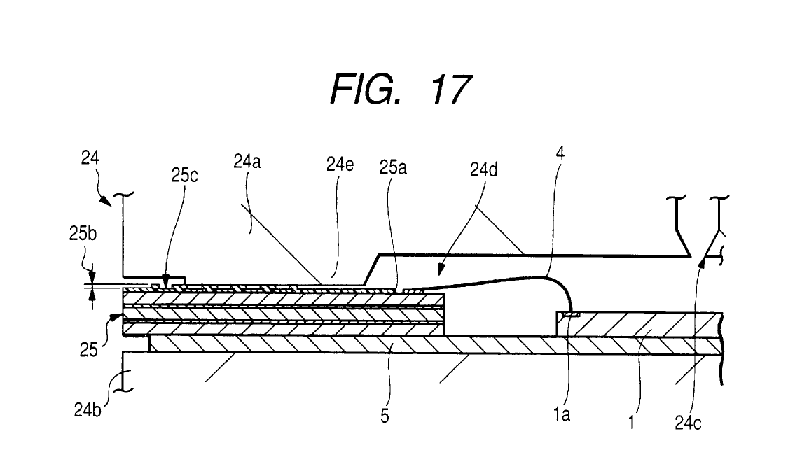

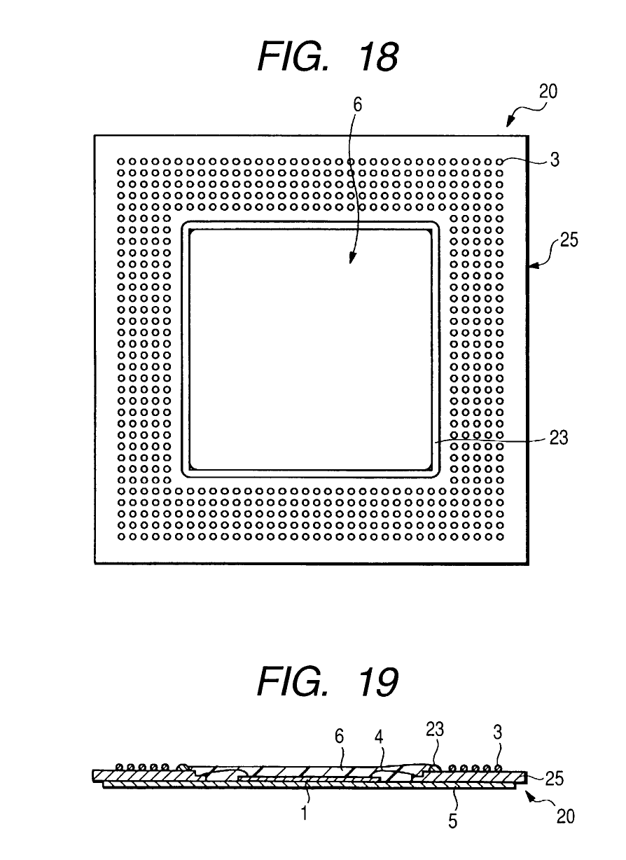

FIGS. 11(a) and 11(b) illustrate structure of a cavity and clamp portion of an upper mold in a molding die which is used in the manufacture of a BGA according to a fourth embodiment of the present invention, in which FIG. 11(a) is a plan view and FIG. 11(b) is an enlarged partial plan view showing a detailed structure of portion A in FIG. 11(a), FIGS. 12(a) and 12(b) show an example of a die clamping state using the upper mold illustrated in FIGS. 11(a) and 11(b), in which FIG. 12(a) is an enlarged partial sectional view and FIG. 12(b) is an enlarged partial sectional view taken along line C-C in FIG. 11(b), FIG. 13 is a plan view showing an example of structure after wire bonding in manufacturing the BGA of the fourth embodiment, FIG. 14 is a sectional view showing a sectional structure taken along line B-B in the substrate illustrated in FIG. 13, FIG. 15 is an enlarged partial sectional view of the substrate shown in FIG. 14, and FIG. 16 is a plan view showing an example of structure after resin molding in manufacturing the BGA of the fourth embodiment.

In this fourth embodiment, a frame-shaped second cavity 12f as another recess, which is shown in FIG. 11(a), is formed around the outside of a cavity 12a of an upper mold (second mold) 12 in a molding die 10, and resin molding is carried out using such an upper mold 12.

At the time of injecting resin in the resin molding step, the second cavity 12f allows the resin leaking outside from the cavity 12a to stay and harden therein, thus preventing the resin from leaking out to the area outside the second cavity 12f, i.e., the area where bump lands 7h are formed.

Therefore, at the time of die clamping, as shown in FIG. 12(a), the solder resist 7f on the bump lands 7h are pressed by only a clamp portion of the upper mold 12.

FIG. 11(a) illustrates the cavity 12a, second cavity 12f and mold surface 12d of the upper mold 12 and also illustrates a positional relation thereof to a substrate 7 in a transmittancewise manner.

Air vents 12g are formed in four corners of the cavity 12a so that the resin injecting step is carried out while allowing air to escape to the exterior through the air vents 12g from the corners of the cavity.

In the upper mold 12 used in this fourth embodiment, a portion is formed inside the second cavity 12f in which portion a sectional height of the cavity 12a is smaller than that of the second cavity 12f, whereby the flow resistance of resin from the cavity 12a to the second cavity 12f in resin molding is made large and the speed of resin flow into the second cavity 12f can be made low.

With this construction, as shown in FIG. 11(b), even where the surface wiring lines 7k are laid spanning the outer periphery of the second cavity 12f, the efflux of resin to the exterior from the second cavity 12f can be prevented almost completely until the resin is filled uniformly into the cavity 12a.

As shown in FIG. 12(b), such an effect is attained by ensuring a sufficient flow resistance of the resin, which is effected by the portion where the sectional height of the cavity 12a becomes smaller. For ensuring such a resin flow resistance it is most preferred to set the aforesaid sectional height of the cavity 12a at zero in the portion where the sectional height becomes smaller. Even where the sectional height cannot be set at zero from problems associated with dimensional accuracy in die machining and dimensional accuracy of the wiring substrate used, it is preferable that the sectional height of the cavity 12a be made smaller than that of each air vent 12g or than the film thickness of each surface wiring line 7k at the portion where the sectional height in question is the smallest.

In this fourth embodiment, there is made no limitation to such internal wiring lines 71 as shown in FIG. 5, but as shown in FIG. 12(b), at a land forming surface 7a of the substrate 7, concaves and convexes may be formed on the surface of solder resist 7f in the area between connecting terminals 7e and bump lands 7h.

That is, at the land forming surface 7a of the substrate 7, wiring lines of a high density can be formed in the area between connecting terminals 7e and bump lands 7h and hence it is possible to use the substrate 7 which is further enhanced in the degree of freedom in wiring as compared with the second embodiment.

Also in this fourth embodiment, at the time of resin molding, the solder resist 7f on the bump lands 7h of the substrate 7 is pressed by only the mold surface 12d of the clamp portion 12c in the upper mold 12. At this time, the pressing can be done without enhancing the clamping force in die clamping, so that even where such internal wiring lines 71 as shown in FIG. 5 are provided, it is possible to effect resin molding without causing disconnection of the internal wiring lines 71.

FIGS. 13, 14 and 15 illustrate the structure after wire bonding of the BGA type semiconductor device assembled in this fourth embodiment, and FIG. 16 illustrates the structure after resin molding.

More specifically, if resin molding is performed using the upper mold 12 shown in FIG. 12(a), a seal portion 6 formed by the cavity 12a and shown in FIG. 16, a secondary molded portion 6a formed in a frame shape by the second cavity 12f, and resinous air vent portions 6b formed by the air vents 12a, are created at the land forming surface 7a of the substrate 7 shown in FIG. 15 after the resin molding.

In case of forming the air vents 12g in the upper mold 12, it is preferable that the air vents 12g be formed at outermost periphery positions, i.e., corners, of the cavity 12a remotest from a gate 12b.

This is because nearby bump lands 7h corresponding to the corners of the cavity 12a are distant from the gate 12b of the upper mold 12 and thus can tolerate a longer time until curing of the resin, so that the efflux of a certain amount of resin from the air vents 12g at the corners is within an allowable range.

Other structural points, how to manufacture, and other effects of the semiconductor device of this fourth embodiment are the same as in the first embodiment, so tautological explanations thereof will here be omitted.

Although the present invention has been described above concretely on the basis of embodiments thereof, it goes without saying that the invention is not limited to the above embodiments, but that various changes may be made within the range not departing from the gist thereof.

For example, although in the above first to fourth embodiments the substrate 7 comprises the wiring substrate 2 and the heat diffusing plate 5, the substrate 7 may be constituted by only the wiring substrate 2 without having the heat diffusing plate 5, and the recess 7b as a cavity may be formed in the wiring substrate 2.

Although in each of the above first to fourth embodiments the semiconductor device is a BGA type semiconductor device, it may of any other type than BGA, e.g., CSP, PGA (Pin Grid Array), or LGA (Land Grip Array), insofar as it has a cavity structure and is assembled through a resin sealing step carried out by transfer molding.

Effects obtained by typical inventions as disclosed herein will be outlined below.

Since a dummy wiring is formed in the main surface area of the substrate located between connecting terminals and external terminal connecting electrodes, at the time of clamping the molding die, the gap between the mold surface of the upper mold and the substrate surface is filled up with the dummy wiring and the solder resist which covers the dummy wiring, thereby bringing about a gap-free state, so that the leakage of sealing resin at the time of injecting the resin can be prevented. As a result, it becomes possible to control the transfer molding stably and hence possible to improve the production efficiency in the molding.

What is claimed is:

1. A method of manufacturing a semiconductor device, comprising the steps of:
providing a substrate, the substrate having a main surface formed with a recess which is enclosed with an inner periphery wall, the substrate further having a plurality of connecting terminals formed around the recess and a plurality of external terminal connecting electrodes which are formed on the main surface so as to be arranged side by side around the connecting terminals;
providing a molding die having first and second molds in a pair, the second mold having a cavity and a second cavity formed around said cavity;
mounting a semiconductor chip in the recess of the substrate;
connecting surface electrodes on the semiconductor chip and the connecting terminals formed around the recess of the substrate with each other through a plurality of metal wires while allowing the metal wires to span the inner periphery wall of the recess;
disposing the substrate onto the first mold and thereafter clamping the substrate by the first and second molds so that a mold surface of the second mold presses the plural external terminal connecting electrodes while allowing the semiconductor chip and the plural metal wires to be covered with the cavity;
injecting a sealing resin into the cavity under pressure to form a seal portion and allowing the sealing resin flowing out from the cavity to be placed into the second cavity and allowing it harden; and
forming a plurality of external terminals on the substrate, the external terminals being electrically connected to the semiconductor chip.

2. A method according to claim 1, wherein the substrate has internal wiring lines in an area between the external terminal connecting electrodes and the connecting terminals.

3. A method according to claim 1, wherein the sealing resin is filled into the cavity while allowing air present within the cavity to escape to the exterior through corners of the cavity.
